(19) United States
(12) Patent Application Publication
(10) Pub. No.: US 2026/0313565 A1
(43) Pub. Date: Oct. 8, 2026

(54) LOW NOISE AMPLIFIER ANALOG GAIN CHANGE COORDINATION FOR NON-COLLOCATED CARRIER AGGREGATION

(71) Applicant: Apple Inc., Cupertino, CA (US)

(72) Inventors: Rolando E. BETTANCOURT ORTEGA, Munich (DE); Qiming LI, Beijing (CN); Yang TANG, San Jose, CA (US); Yuexia SONG, Beijing (CN); Dawei ZHANG, Saratoga, CA (US); Prabin Kumar PANDEY, Vaterstetten (DE)

(21) Appl. No.: 19/482,635

(22) PCT Filed: May 11, 2023
(86) PCT No.: PCT/CN2023/093554

§ 371 Date: Nov. 7, 2025

(51) Int. Cl. H04W 52/52; H04B 7/06; H04L 5/00; H04W 72/1273

(52) U.S. Cl. CPC H04W 52/52; H04B 7/0626; H04L 5/0044; H04W 72/1273

(57) ABSTRACT

In one aspect, a network may perform a method including determining one or more among a plurality of slots that an analog gain change of an automatic gain control (AGC) process is permitted, and signaling to a user equipment (UE) that is coupled to or in communication with the network, the one or more of the plurality of slots that the analog gain change is permitted. The network may schedule downlink based on the one or more of the plurality of slots that the analog gain change is permitted.

### FIELD OF INVENTION

This invention relates generally to wireless technology and more particularly to communications involving non-collocated carrier aggregation.

### BACKGROUND

Fifth generation mobile network (5G) is a wireless standard that aims to improve upon data transmission speed, reliability, availability, and more. The wireless standard includes numerous procedures that may be implemented by a transmitting device or a receiving device that improves the latency, the speed, and the reliability of uplink and downlink transmissions.

### SUMMARY

Aspects of the present disclosure relate to 5G new radio (NR) operating in the licensed spectrum or in the shared and unlicensed spectrum (NR-U).

In one aspect, a method, performed by a network, includes determining one or more among a plurality of slots that an analog gain change of an automatic gain control (AGC) process is permitted, and signaling to a user equipment (UE) that is associated with or in communication with the network, the one or more of the plurality of slots that the analog gain change is permitted. The method also includes scheduling downlink based on the one or more of the plurality of slots that the analog gain change is permitted.

In an embodiment, scheduling the downlink may include for each of the one or more of the plurality of slots that the analog gain change is permitted, scheduling a restricted physical data shared channel (PDSCH). Similarly, scheduling the downlink may include for each remaining slots of the plurality of slots, scheduling a PDSCH with a full range of orthogonal frequency division multiplexing (OFDM) symbols.

In an embodiment, determining the one or more of the plurality of slots that the analog gain change is permitted may include receiving one or more network measurements from the UE, determining a cadence of the analog gain change according to the one or more network measurements from the UE, and determining the one or more slots based on the determined cadence of the analog gain change.

In an embodiment, performing the AGC process includes performing an analog gain change during the one or more of the plurality of slots that the analog gain change is permitted and not performing the analog gain change during remaining slots of the plurality of slots. Performing the AGC process may include performing a digital gain change during the remaining slots of the plurality of slots. The one or more of the plurality of slots that the analog gain change is permitted may be referred to as restricted slots. The remaining slots may be referred to as unrestricted slots.

In an embodiment, signaling to the UE the one or more slots that the analog gain change is permitted includes signaling an integer to the UE, where the UE applies the integer as a modulation parameter to each of the plurality of slots to obtain the one or more of the plurality of slots that the analog gain change is permitted.

In an embodiment, the restricted PDSCH includes a full range of OFDM symbols except for a first symbol. In another example, the restricted PDSCH includes a full range of OFDM symbols except for a last symbol.

In an embodiment, the one or more network measurements include a channel state information reference signal (CSI-RS) measurement of the network taken by the UE.

In one aspect, a method, performed by user equipment (UE) that is associated with or in communication with a network, includes receiving, from the network, one or more among a plurality of slots that an analog gain change of an automatic gain control (AGC) process is permitted, where the one or more of the plurality of slots that the analog gain change is permitted is determined by the network, performing the AGC process according to the one or more slots that the analog gain change is permitted, and receiving a downlink scheduled by the network based on the one or more slots that the analog gain change is permitted.

In one aspect, a base station, comprises a transceiver configured to communicate with a user equipment (UE), and a processor communicatively coupled to the transceiver and configured to perform the methods described herein from the perspective of the network.

In one aspect, a processor (e.g., a baseband processor) of a UE is configured to perform the methods described herein from the perspective of the UE.

Other technical features may be readily apparent to one skilled in the art from the following figures, descriptions, and claims.

### BRIEF DESCRIPTION OF THE DRAWINGS

The present invention is illustrated by way of example and not limitation in the figures of the accompanying drawings in which like references indicate similar elements.

FIG. 1 illustrates an example wireless communication system according to some aspects.

FIG. 2 illustrates uplink and downlink communications according to some aspects.

FIG. 3 illustrates an example block diagram of a user equipment (UE) according to some aspects.

FIG. 4 illustrates an example block diagram of a base station (BS) according to some aspects.

FIG. 5 illustrates an example block diagram of cellular communication circuitry, according to some aspects.

FIG. 6 shows an example of analog gain control with a receive chain 604, according to some aspects.

FIG. 7 shows a table of UE characteristics, according to some aspects.

FIG. 8 shows a method 800 for coordination of AGC from a network perspective, according to some aspects.

FIG. 9 shows a method 900 for coordination of AGC from a UE perspective, according to some aspects.

FIG. 10 shows a diagram illustrating example operations for coordinating automatic gain change (AGC) between user equipment and a network, according to some aspects.

### DETAILED DESCRIPTION

A method and apparatus of a device that communicates wirelessly with a network to coordinate low noise amplifier (LNA) analog gain change (AGC) for intra-band non-collocated (NC) carrier aggregation (CA) in a new radio (NR) environment are described. It will be apparent, however, to one skilled in the art, that aspects of the present disclosure may be practiced without these specific details. In other instances, well-known components, structures, and techniques have not been shown in detail in order not to obscure the understanding of this description.

Reference in the specification to “some aspects” or “an aspect” means that a particular feature, structure, or characteristic described in connection with the aspect can be included in at least one aspect of the disclosure. The appearances of the phrase “in some aspects” in various places in the specification do not necessarily all refer to the same aspect.

In the following description and claims, the terms “coupled” and “connected,” along with their derivatives, may be used. “Coupled” is used to indicate that two or more elements, which may or may not be in direct physical or electrical contact with each other, co-operate or interact with each other. “Connected” is used to indicate the establishment of communication between two or more elements that are coupled with each other.

The processes depicted in the figures that follow, are performed by processing logic that comprises hardware (e.g., circuitry, dedicated logic, etc.), software (such as is run on a general-purpose computer system or a dedicated machine), or a combination of both. Although the processes are described below in terms of some sequential operations, it should be appreciated that some of the operations described may be performed in different order. Moreover, some operations may be performed in parallel rather than sequentially.

The terms “server,” “client,” and “device” are intended to refer generally to data processing systems rather than specifically to a particular form factor for the server, client, and/or device.

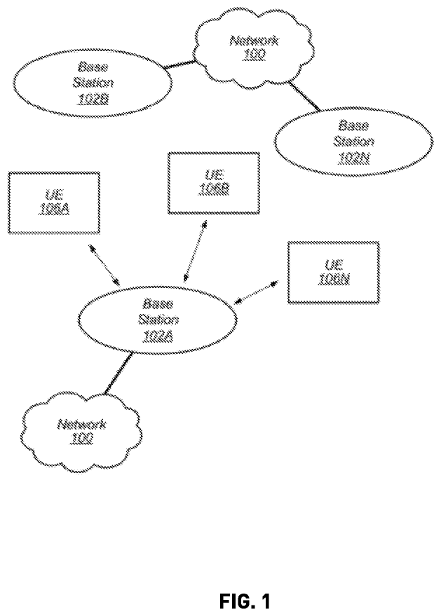

FIG. 1 illustrates a simplified example wireless communication system, according to some aspects. It is noted that the system of FIG. 1 is merely one example of a possible system, and that features of this disclosure may be implemented in any of various systems, as desired.

As shown, the example wireless communication system includes a base station 102A which communicates over a transmission medium with one or more user devices 106A, 106B, etc., through 106N. Each of the user devices may be referred to as a “user equipment” (UE).

The base station (BS) 102A may be a base transceiver station (BTS) or cell site (a “cellular base station”) and may include hardware that enables wireless communication with the UEs 106A through 106N.

The communication area (or coverage area) of the base station may be referred to as a “cell.” The base station 102A and the UEs 106 may be configured to communicate over the transmission medium using any of various radio access technologies (RATs), also referred to as wireless communication technologies, or telecommunication standards, such as GSM, UMTS (associated with, for example, WCDMA or TD-SCDMA air interfaces), LTE, LTE-Advanced (LTE-A), 5G new radio (5G NR), HSPA, 3GPP2 CDMA 2000 (e.g., 1xRTT, 1xEV-DO, HRPD, eHRPD), etc. Note that if the base station 102A is implemented in the context of LTE, it may alternately be referred to as an ‘eNodeB’ or ‘eNB’. Note that if the base station 102A is implemented in the context of 5G NR, it may alternately be referred to as ‘gNodeB’or ‘gNB’.

As shown, the base station 102A may also be equipped to communicate with a network 100 (e.g., a core network of a cellular service provider, a telecommunication network such as a public switched telephone network (PSTN), and/or the Internet, among various possibilities). Thus, the base station 102A may facilitate communication between the user devices and/or between the user devices and the network 100. In particular, the cellular base station 102A may provide UEs 106 with various telecommunication capabilities, such as voice, SMS and/or data services.

Base station 102A and other similar base stations (such as base stations 102B . . . 102N) operating according to the same or a different cellular communication standard may thus be provided as a network of cells, which may provide continuous or nearly continuous overlapping service to UEs 106A-N and similar devices over a geographic area via one or more cellular communication standards.

Thus, while base station 102A may act as a “serving cell” for UEs 106A-N as illustrated in FIG. 1, each UE 106 may also be capable of receiving signals from (and possibly within communication range of) one or more other cells (which might be provided by base stations 102B-N and/or any other base stations), which may be referred to as “neighboring cells”. Such cells may also be capable of facilitating communication between user devices and/or between user devices and the network 100. Such cells may include “macro” cells, “micro” cells, “pico” cells, and/or cells which provide any of various other granularities of service area size. For example, base stations 102A-B illustrated in FIG. 1 might be macro cells, while base station 102N might be a micro cell. Other configurations are also possible.

In some aspects, base station 102A may be a next generation base station, e.g., a 5G New Radio (5G NR) base station, or “gNB”. In some aspects, a gNB may be connected to a legacy evolved packet core (EPC) network and/or to a NR core (NRC) network. In addition, a gNB cell may include one or more transition and reception points (TRPs). In addition, a UE capable of operating according to 5G NR may be connected to one or more TRPs within one or more gNBs.

Note that a UE 106 may be capable of communicating using multiple wireless communication standards. For example, the UE 106 may be configured to communicate using a wireless networking (e.g., Wi-Fi) and/or peer-to-peer wireless communication protocol (e.g., Bluetooth, Wi-Fi peer-to-peer, etc.) in addition to at least one cellular communication protocol (e.g., GSM, UMTS (associated with, for example, WCDMA or TD-SCDMA air interfaces), LTE, LTE-A, 5G NR, HSPA, 3GPP2 CDMA 2000 (e.g., 1xRTT, 1xEV-DO, HRPD, eHRPD), etc.). The UE 106 may also or alternatively be configured to communicate using one or more global navigational satellite systems (GNSS, e.g., GPS or GLONASS), one or more mobile television broadcasting standards (e.g., ATSC-M/H or DVB-H), and/or any other wireless communication protocol, if desired. Other combinations of wireless communication standards (including more than two wireless communication standards) are also possible.

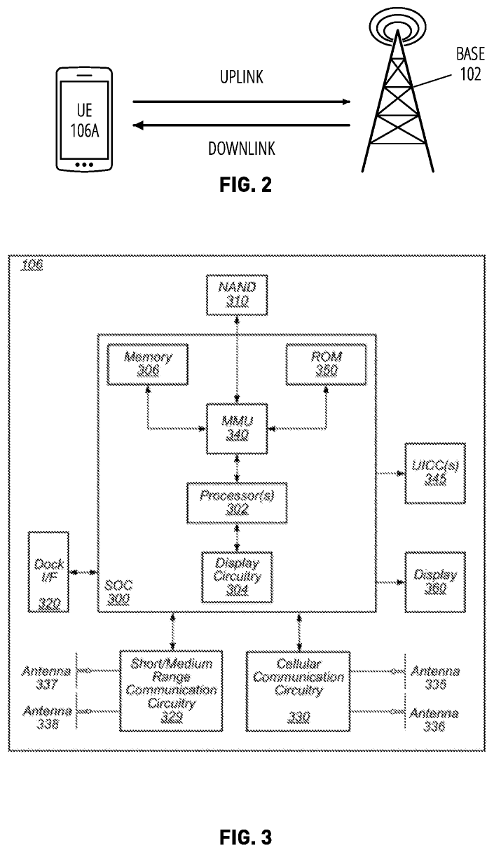

FIG. 2 illustrates UE 106A that can be in communication with a base station 102 through uplink and downlink communications, according to some aspects. The UEs may each be a device with cellular communication capability such as a mobile phone, a hand-held device, a computer or a tablet, or virtually any type of wireless device.

The UE may include a processor that is configured to execute program instructions stored in memory. The UE may perform any of the method aspects described herein by executing such stored instructions. Alternatively, or in addition, the UE may include a programmable hardware element such as an FPGA (field-programmable gate array) that is configured to perform any of the method aspects described herein, or any portion of any of the method aspects described herein.

The UE may include one or more antennas for communicating using one or more wireless communication protocols or technologies. In some aspects, the UE may be configured to communicate using, for example, CDMA2000 (1xRTT/1xEV-DO/HRPD/eHRPD) or LTE using a single shared radio and/or GSM or LTE using the single shared radio. The shared radio may couple to a single antenna, or may couple to multiple antennas (e.g., for MIMO) for performing wireless communications. In general, a radio may include any combination of a baseband processor, analog RF signal processing circuitry (e.g., including filters, mixers, oscillators, amplifiers, etc.), or digital processing circuitry (e.g., for digital modulation as well as other digital processing). Similarly, the radio may implement one or more receive and transmit chains using the aforementioned hardware. For example, the UE 106 may share one or more parts of a receive and/or transmit chain between multiple wireless communication technologies, such as those discussed above.

In some aspects, the UE may include separate transmit and/or receive chains (e.g., including separate antennas and other radio components) for each wireless communication protocol with which it is configured to communicate. As a further possibility, the UE may include one or more radios which are shared between multiple wireless communication protocols, and one or more radios which are used exclusively by a single wireless communication protocol. For example, the UE might include a shared radio for communicating using either of LTE or 5G NR (or LTE or 1xRTTor LTE or GSM), and separate radios for communicating using each of Wi-Fi and Bluetooth. Other configurations are also possible.

FIG. 3 illustrates an example simplified block diagram of a communication device 106, according to some aspects. It is noted that the block diagram of the communication device of FIG. 3 is only one example of a possible communication device. According to aspects, communication device 106 may be a UE device, a mobile device or mobile station, a wireless device or wireless station, a desktop computer or computing device, a mobile computing device (e.g., a laptop, notebook, or portable computing device), a tablet and/or a combination of devices, among other devices. As shown, the communication device 106 may include a set of components 300 configured to perform core functions. For example, this set of components may be implemented as a system on chip (SOC), which may include portions for various purposes. Alternatively, this set of components 300 may be implemented as separate components or groups of components for the various purposes. The set of components 300 may be coupled (e.g., communicatively; directly or indirectly) to various other circuits of the communication device 106.

For example, the communication device 106 may include various types of memory (e.g., including NAND flash 310), an input/output interface such as connector I/F 320 (e.g., for connecting to a computer system; dock; charging station; input devices, such as a microphone, camera, keyboard; output devices, such as speakers; etc.), the display 360, which may be integrated with or external to the communication device 106, and cellular communication circuitry 330 such as for 5G NR, LTE, GSM, etc., and short to medium range wireless communication circuitry 329 (e.g., Bluetooth™ and WLAN circuitry). In some aspects, communication device 106 may include wired communication circuitry (not shown), such as a network interface card, e.g., for Ethernet.

The cellular communication circuitry 330 may couple (e.g., communicatively; directly or indirectly) to one or more antennas, such as antennas 335 and 336 as shown. The short to medium range wireless communication circuitry 329 may also couple (e.g., communicatively; directly or indirectly) to one or more antennas, such as antennas 337 and 338 as shown. Alternatively, the short to medium range wireless communication circuitry 329 may couple (e.g., communicatively; directly or indirectly) to the antennas 335 and 336 in addition to, or instead of, coupling (e.g., communicatively; directly or indirectly) to the antennas 337 and 338. The short to medium range wireless communication circuitry 329 and/or cellular communication circuitry 330 may include multiple receive chains and/or multiple transmit chains for receiving and/or transmitting multiple spatial streams, such as in a multiple-input multiple output (MIMO) configuration.

In some aspects, as further described below, cellular communication circuitry 330 may include dedicated receive chains (including and/or coupled to, e.g., communicatively; directly or indirectly. dedicated processors and/or radios) for multiple radio access technologies (RATs) (e.g., a first receive chain for LTE and a second receive chain for 5G NR). In addition, in some aspects, cellular communication circuitry 330 may include a single transmit chain that may be switched between radios dedicated to specific RATs. For example, a first radio may be dedicated to a first RAT, e.g., LTE, and may be in communication with a dedicated receive chain and a transmit chain shared with an additional radio, e.g., a second radio that may be dedicated to a second RAT, e.g., 5G NR, and may be in communication with a dedicated receive chain and the shared transmit chain.

The communication device 106 may also include and/or be configured for use with one or more user interface elements. The user interface elements may include any of various elements, such as display 360 (which may be a touchscreen display), a keyboard (which may be a discrete keyboard or may be implemented as part of a touchscreen display), a mouse, a microphone and/or speakers, one or more cameras, one or more buttons, and/or any of various other elements capable of providing information to a user and/or receiving or interpreting user input.

The communication device 106 may further include one or more smart cards 345 that include SIM (Subscriber Identity Module) functionality, such as one or more UICC(s) (Universal Integrated Circuit Card(s)) cards 345.

As shown, the SOC 300 may include processor(s) 302, which may execute program instructions for the communication device 106 and display circuitry 304, which may perform graphics processing and provide display signals to the display 360. The processor(s) 302 may also be coupled to memory management unit (MMU) 340, which may be configured to receive addresses from the processor(s) 302 and translate those addresses to locations in memory (e.g., memory 306, read only memory (ROM) 350, NAND flash memory 310) and/or to other circuits or devices, such as the display circuitry 304, short range wireless communication circuitry 229, cellular communication circuitry 330, connector I/F 320, and/or display 360. The MMU 340 may be configured to perform memory protection and page table translation or set up. In some aspects, the MMU 340 may be included as a portion of the processor(s) 302.

As noted above, the communication device 106 may be configured to communicate using wireless and/or wired communication circuitry. The communication device 106 may also be configured to determine a physical downlink shared channel scheduling resource for a user equipment device and a base station. Further, the communication device 106 may be configured to group and select CCs from the wireless link and determine a virtual CC from the group of selected CCs. The wireless device may also be configured to perform a physical downlink resource mapping based on an aggregate resource matching patterns of groups of CCs.

As described herein, the communication device 106 may include hardware and software components for implementing the above features for determining a physical downlink shared channel scheduling resource for a communications device 106 and a base station. The processor 302 of the communication device 106 may be configured to implement part or all of the features described herein, e.g., by executing program instructions stored on a memory medium (e.g., a non-transitory computer-readable memory medium). Alternatively (or in addition), processor 302 may be configured as a programmable hardware element, such as an FPGA (Field Programmable Gate Array), or as an ASIC (Application Specific Integrated Circuit). Alternatively (or in addition) the processor 302 of the communication device 106, in conjunction with one or more of the other components 300, 304, 306, 310, 320, 329, 330, 340, 345, 350, 360 may be configured to implement part or all of the features described herein.

In addition, as described herein, processor 302 may include one or more processing elements. Thus, processor 302 may include one or more integrated circuits (ICs) that are configured to perform the functions of processor 302. In addition, each integrated circuit may include circuitry (e.g., first circuitry, second circuitry, etc.) configured to perform the functions of processor(s) 302.

Further, as described herein, cellular communication circuitry 330 and short-range wireless communication circuitry 329 may each include one or more processing elements. In other words, one or more processing elements may be included in cellular communication circuitry 330 and, similarly, one or more processing elements may be included in short range wireless communication circuitry 329. Thus, cellular communication circuitry 330 may include one or more integrated circuits (ICs) that are configured to perform the functions of cellular communication circuitry 330. In addition, each integrated circuit may include circuitry (e.g., first circuitry, second circuitry, etc.) configured to perform the functions of cellular communication circuitry 230. Similarly, the short-range wireless communication circuitry 329 may include one or more ICs that are configured to perform the functions of short-range wireless communication circuitry 32. In addition, each integrated circuit may include circuitry (e.g., first circuitry, second circuitry, etc.) configured to perform the functions of short-range wireless communication circuitry 329.

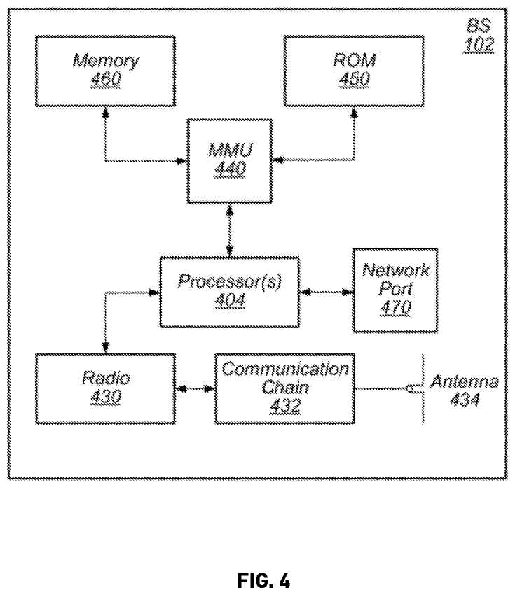

FIG. 4 illustrates an example block diagram of a base station 102, according to some aspects. It is noted that the base station of FIG. 4 is merely one example of a possible base station. As shown, the base station 102 may include processor(s) 404 which may execute program instructions for the base station 102. The processor(s) 404 may also be coupled to memory management unit (MMU) 440, which may be configured to receive addresses from the processor(s) 404 and translate those addresses to locations in memory (e.g., memory 460 and read only memory (ROM) 450) or to other circuits or devices.

The base station 102 may include at least one network port 470. The network port 470 may be configured to couple to a telephone network and provide a plurality of devices, such as UE devices 106, access to the telephone network as described above in FIGS. 1 and 2.

The network port 470 (or an additional network port) may also or alternatively be configured to couple to a cellular network, e.g., a core network of a cellular service provider. The core network may provide mobility related services and/or other services to a plurality of devices, such as UE devices 106. In some cases, the network port 470 may couple to a telephone network via the core network, and/or the core network may provide a telephone network (e.g., among other UE devices serviced by the cellular service provider).

In some aspects, base station 102 may be a next generation base station, e.g., a 5G New Radio (5G NR) base station, or “gNB”. In such aspects, base station 102 may be connected to a legacy evolved packet core (EPC) network and/or to a NR core (NRC) network. In addition, base station 102 may be considered a 5G NR cell and may include one or more transition and reception points (TRPs). In addition, a UE capable of operating according to 5G NR may be connected to one or more TRPs within one or more gNBs. In some aspects, the base station can operate in 5G NR-U mode.

The base station 102 may include at least one antenna 434, and possibly multiple antennas. The at least one antenna 434 may be configured to operate as a wireless transceiver and may be further configured to communicate with UE devices 106 via radio 430. The antenna 434 communicates with the radio 430 via communication chain 432. Communication chain 432 may be a receive chain, a transmit chain or both. The radio 430 may be configured to communicate via various wireless communication standards, including, but not limited to, 5G NR, 5G NR-U, LTE, LTE-A, GSM, UMTS, CDMA 2000, Wi-Fi, etc.

The base station 102 may be configured to communicate wirelessly using multiple wireless communication standards. In some instances, the base station 102 may include multiple radios, which may enable the base station 102 to communicate according to multiple wireless communication technologies. For example, as one possibility, the base station 102 may include an LTE radio for performing communication according to LTE as well as a 5G NR radio for performing communication according to 5G NR and 5G NR-U. In such a case, the base station 102 may be capable of operating as both an LTE base station and a 5G NR base station. As another possibility, the base station 102 may include a multi-mode radio which is capable of performing communications according to any of multiple wireless communication technologies (e.g., 5G NR and Wi-Fi, LTE and Wi-Fi, LTE and UMTS, LTE and CDMA2000, UMTS and GSM, etc.).

As described further subsequently herein, the BS 102 may include hardware and software components for implementing or supporting implementation of features described herein. The processor 404 of the base station 102 may be configured to implement or support implementation of part or all of the methods described herein, e.g., by executing program instructions stored on a memory medium (e.g., a non-transitory computer-readable memory medium). Alternatively, the processor 404 may be configured as a programmable hardware element, such as an FPGA (Field Programmable Gate Array), or as an ASIC (Application Specific Integrated Circuit), or a combination thereof. Alternatively (or in addition) the processor 404 of the BS 102, in conjunction with one or more of the other components 430, 432, 434, 440, 450, 460, 470 may be configured to implement or support implementation of part or all of the features described herein.

In addition, as described herein, processor(s) 404 may be comprised of one or more processing elements. In other words, one or more processing elements may be included in processor(s) 404. Thus, processor(s) 404 may include one or more integrated circuits (ICs) that are configured to perform the functions of processor(s) 404. In addition, each integrated circuit may include circuitry (e.g., first circuitry, second circuitry, etc.) configured to perform the functions of processor(s) 404.

Further, as described herein, radio 430 may be comprised of one or more processing elements. In other words, one or more processing elements may be included in radio 430. Thus, radio 430 may include one or more integrated circuits (ICs) that are configured to perform the functions of radio 430. In addition, each integrated circuit may include circuitry (e.g., first circuitry, second circuitry, etc.) configured to perform the functions of radio 430.

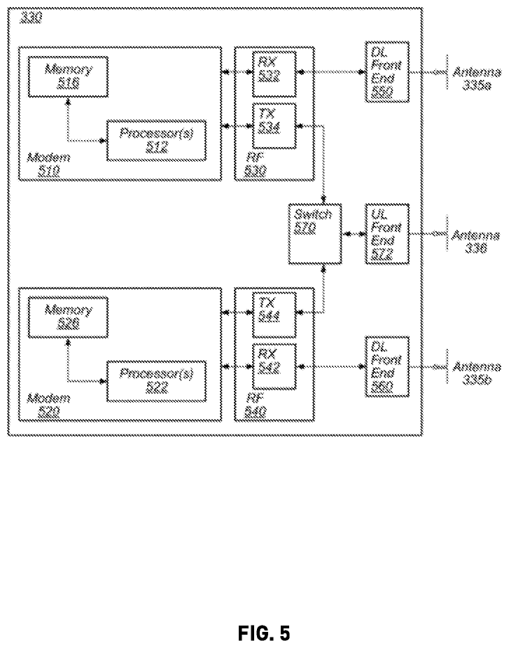

FIG. 5 illustrates an example simplified block diagram of cellular communication circuitry, according to some aspects. It is noted that the block diagram of the cellular communication circuitry of FIG. 5 is only one example of a possible cellular communication circuit. According to aspects, cellular communication circuitry 330 may be included in a communication device, such as communication device 106 described above. As noted above, communication device 106 may be a user equipment (UE) device, a mobile device or mobile station, a wireless device or wireless station, a desktop computer or computing device, a mobile computing device (e.g., a laptop, notebook, or portable computing device), a tablet and/or a combination of devices, among other devices.

The cellular communication circuitry 330 may couple (e.g., communicatively; directly or indirectly) to one or more antennas, such as antennas 335 a-b and 336 as shown (in FIG. 3). In some aspects, cellular communication circuitry 330 may include dedicated receive chains (including and/or coupled to, e.g., communicatively; directly or indirectly. dedicated processors and/or radios) for multiple RATs (e.g., a first receive chain for LTE and a second receive chain for 5G NR). For example, as shown in FIG. 5, cellular communication circuitry 330 may include a modem 510 and a modem 520. Modem 510 may be configured for communications according to a first RAT, e.g., such as LTE or LTE-A, and modem 520 may be configured for communications according to a second RAT, e.g., such as 5G NR.

As shown, modem 510 may include one or more processors 512 and a memory 516 in communication with processors 512. Modem 510 may be in communication with a radio frequency (RF) front end 530. RF front end 530 may include circuitry for transmitting and receiving radio signals. For example, RF front end 530 may include receive circuitry (RX) 532 and transmit circuitry (TX) 534. In some aspects, receive circuitry 532 may be in communication with downlink (DL) front end 550, which may include circuitry for receiving radio signals via antenna 335a.

Similarly, modem 520 may include one or more processors 522 and a memory 526 in communication with processors 522. Modem 520 may be in communication with an RF front end 540. RF front end 540 may include circuitry for transmitting and receiving radio signals. For example, RF front end 540 may include receive circuitry 542 and transmit circuitry 544. In some aspects, receive circuitry 542 may be in communication with DL front end 560, which may include circuitry for receiving radio signals via antenna 335b.

In some aspects, a switch 570 may couple transmit circuitry 534 to uplink (UL) front end 572. In addition, switch 570 may couple transmit circuitry 544 to UL front end 572. UL front end 572 may include circuitry for transmitting radio signals via antenna 336. Thus, when cellular communication circuitry 330 receives instructions to transmit according to the first RAT (e.g., as supported via modem 510), switch 570 may be switched to a first state that allows modem 510 to transmit signals according to the first RAT (e.g., via a transmit chain that includes transmit circuitry 534 and UL front end 572). Similarly, when cellular communication circuitry 330 receives instructions to transmit according to the second RAT (e.g., as supported via modem 520), switch 570 may be switched to a second state that allows modem 520 to transmit signals according to the second RAT (e.g., via a transmit chain that includes transmit circuitry 544 and UL front end 572).

As described herein, the modem 510 may include hardware and software components for implementing the above features or for determining a physical downlink shared channel scheduling resource for a user equipment device and a base station, as well as the various other techniques described herein. The processors 512 may be configured to implement part or all of the features described herein, e.g., by executing program instructions stored on a memory medium (e.g., a non-transitory computer-readable memory medium). Alternatively (or in addition), processor 512 may be configured as a programmable hardware element, such as an FPGA (Field Programmable Gate Array), or as an ASIC (Application Specific Integrated Circuit). Alternatively (or in addition) the processor 512, in conjunction with one or more of the other components 530, 532, 534, 550, 570, 572, 335 and 336 may be configured to implement part or all of the features described herein.

In addition, as described herein, processors 512 may include one or more processing elements. Thus, processors 512 may include one or more integrated circuits (ICs) that are configured to perform the functions of processors 512. In addition, each integrated circuit may include circuitry (e.g., first circuitry, second circuitry, etc.) configured to perform the functions of processors 512.

As described herein, the modem 520 may include hardware and software components for implementing the above features for determining a physical downlink shared channel scheduling resource for a user equipment device and a base station, as well as the various other techniques described herein. The processors 522 may be configured to implement part or all of the features described herein, e.g., by executing program instructions stored on a memory medium (e.g., a non-transitory computer-readable memory medium). Alternatively (or in addition), processor 522 may be configured as a programmable hardware element, such as an FPGA (Field Programmable Gate Array), or as an ASIC (Application Specific Integrated Circuit). Alternatively (or in addition) the processor 522, in conjunction with one or more of the other components 540, 542, 544, 550, 570, 572, 335 and 336 may be configured to implement part or all of the features described herein.

In addition, as described herein, processors 522 may include one or more processing elements. Thus, processors 522 may include one or more integrated circuits (ICs) that are configured to perform the functions of processors 522. In addition, each integrated circuit may include circuitry (e.g., first circuitry, second circuitry, etc.) configured to perform the functions of processors 522.

5G supports multi-antenna transmission, beam-forming, and simultaneous transmission from multiple geographically separates sites. Channels of different antenna ports that are relevant for a UE may differ, for example, in terms of radio channel properties. QCL antenna port may be geographically separated.

5G physical channels provide flexible communication between the 5G base stations and the UEs. 5G NR has specified the physical channels for 5G networks that can be used either for Downlink or Uplink communication. 5G NR physical channels used for uplink communication includes the physical uplink shared channel (PUSCH), the physical uplink control channel (PUCCH), and the physical random-access channel (PRACH). Uplink signals such as DM-RS, PT-RS, and SRS are also supported. 5G NR supports the simultaneous transmission on PUSCH and PUCCH. PUSCH is typically used to carry the user data and optionally, can carry uplink control information (UCI).

PDSCH stands for Physical Downlink Shared Channel and is a channel used to deliver data from the base station (e.g., gNb) to the user equipment (UE) in the downlink direction.

PDSCH supports high data rates and low latency for a wide range of applications and services. It uses advanced modulation and coding schemes, as well as multiple antenna techniques such as MIMO (Multiple Input Multiple Output), to maximize spectral efficiency and improve the overall performance of the network. PDSCH is also used in conjunction with other channels, such as the Physical Downlink Control Channel (PDCCH) and Physical Hybrid ARQ Indicator Channel (PHICH), to support features such as channel state information reporting, scheduling and retransmission of data packets, and HARQ (Hybrid Automatic Repeat Request) feedback. PDSCH enables the delivery of high-speed data and low-latency services to users in the downlink direction, and supports a range of advanced features and capabilities that promote efficient and reliable operation of the network.

In the present disclosure, operations described may optimally perform a coordinated low noise amplifier (LNA) analog gain change (AGC) for intra-band non-collocated (NC) carrier aggregation (CA) in a new radio (NR) environment. Phase jumps may be expected to occur at any time, such as, for example, when the user equipment (UE) performs analog gain control (AGC). AGC is an operation performed in wireless communication systems to adjust the amplitude of the received signal. AGC adjusts the received signal power within a certain range to improve the signal-to-noise ratio (SNR) and reduce distortion. AGC may be implemented in the receiver circuitry of a UE to adjust the gain of the analog front-end before the signal is digitized by the analog-to-digital converter (ADC). The gain control may be performed by adjusting the amplification factor of the amplifier in the receiver, or by applying a digital filter to the digitized signal, or both. The AGC process may be based on the feedback loop mechanism that continuously monitors the received signal power and adjusts the gain to maintain a constant power level so that the signal is neither too weak nor too strong, which can cause distortion or saturation of the ADC converter.

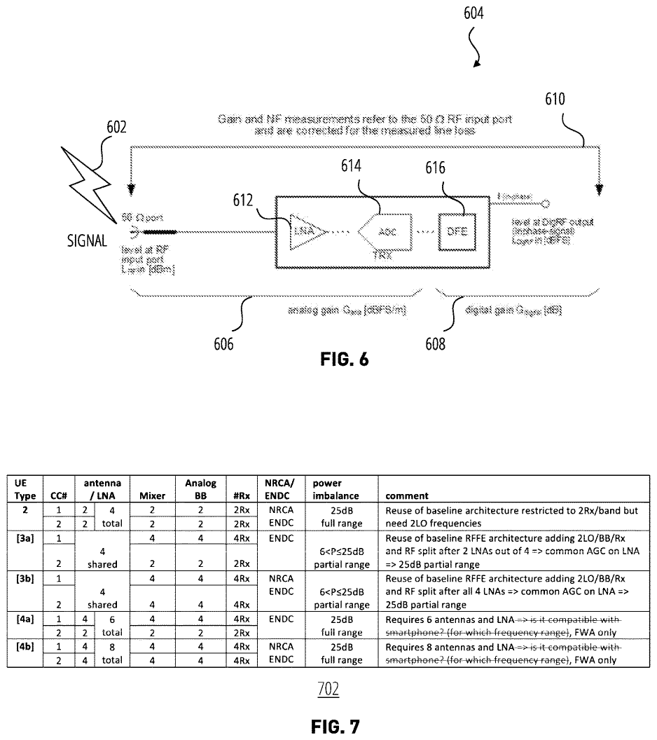

FIG. 6 shows an example of analog gain control with a receive chain 604, in accordance with some aspects. Receive chain 604 may include radio frequency (RF) circuitry such as, for example, one or more low noise amplifiers 612 to receive and amplify the input signal 602 and one or more analog digital converters 614 to digitize the amplified signal from the low noise amplifier 612. The RF circuitry may be responsible for performing analog gain 606. A digital front end 616 may receive the digital signal and perform further amplification. The LNA 612 and/or ADC 614 may be adjusted by a UE as part of the analog gain adjustment operation. The digital front end 616 and processing downstream of that may be adjusted as part of the digital gain adjustment.

The receive chain 604 may be part of a complete receive (RX) chain of a UE such as UE 106 or any of the UEs shown or described in another section. Some parts of the complete receive chain may be omitted here for clarity. AGC reduces the signal to noise (SNR) degradation of signal 602 caused by distortions and quantization noise. AGC further reduces or prevents RX signal clipping of signal 602.

AGC, which includes automatic gain adjustment through adjustment of the analog gain 606 or digital gain 608, regulates the received signal strength of a signal 602 in a manner that fully utilizes the RX chain dynamic range. Processing logic of a UE may adjust analog gain 606 or digital gain 608 through adjusting the one or more LNAs 612 (e.g., register values or other hardware-based adjustments) in the receive chain 604, or digital filtering algorithms at the digital front end 616, to adjust the respective gains.

Typically, with AGC, Total Gain 610=Analog gain 606+Digital gain 608. When the UE makes a change to analog gain 606 (e.g., through an adjustment to RF circuits), this produces a “phase jump” on time-domain samples in the range of 0~360 degrees. A change to digital gain 608 will not. Phase jumps caused by analog gain state change can be detrimental to channel and parameter estimation if the phase jump are not handled properly.

A UE may perform AGC to update the gain at different speeds. A typical update speed may take between one and a handful of slots, depending on input signal, channel conditions, or both. A slot may be referred to as a fixed time interval that is used for transmitting and receiving data between the UE and the network (e.g., through a BS). Each slot may have a fixed duration (e.g., 0.125 milliseconds (ms)) and is further divided into smaller sub-slots, which may be referred to as symbols. By dividing the available radio resources into fixed time intervals, the network may efficiently allocate resources to different devices and applications, while also minimizing interference and maximizing overall network capacity. For example, each slot can be assigned to a specific device or application, depending on the network's needs and the resources available at any given time. Further, some slots may be designed by the network as ‘restricted’, while remaining slots are unrestricted, as described on other sections. The allocation of slots to applications and devices, and the adjustment of slot duration may be referred to as scheduling.

The network and UE may coordinate with each other to restrict use of some symbols if it is known when a phase jump may occur, to schedule around affected symbols. An example of restricted version of PDSCH is if one or more symbols are restricted and cannot be used. For example, integrity of a first symbol (e.g., symbol 0) or a last symbol (e.g., symbol 13) may become compromised due to a phase jump that causes a symbol to get stepped on or ‘clipped’. Thus, the UE and network may communicate with each other to agree on which slots an analog gain change may be performed by the UE, during which the network could then schedule restricted slots.

A brute force approach may be to restrict every downlink signal but the network (e.g., gNB) may lose potential throughput if the network scheduled every slot as a restricted version of physical downlink side channel (PDSCH). Thus, a more nuanced approach may be taken to restrict the PDSCH at only certain slots, and communicate this to the UE so that the UE may restrict analog gain 606 change to occur only at those slots.

Processes described in the present disclosure may signal the UE when analog change is allowed, such that the network knows when only a digital change can be applied. This may allow for PDSCH scheduling where the slots utilize all OFDM symbols rather than a restricted subset of the symbols, which may provide improved results for Non-Collocated Carrier Aggregation (NC-CA).

Carrier aggregation (CA) is a technology used in 5G networks to combine multiple frequency bands or carriers to increase the bandwidth and data transfer rates of the network. With carrier aggregation, multiple carriers with different frequency bands can be combined and treated as a single, wider channel for data transmission. This promotes efficient use of the available spectrum, higher data transfer rates, and improved network performance. For example, in a typical 5G network, a mobile device may use carrier aggregation to combine two or more carriers with different frequency bands, such as, for example, 700 MHz and 2.5 GHz, to achieve a wider channel and faster download and upload speeds. Carrier aggregation enables the network to support a large number of devices and high-bandwidth applications.

NC-CA allows mobile network operators to aggregate multiple frequency bands that are not physically located in the same location or site. NC-CA enables the combining of frequency bands that are deployed in different locations (e.g., in different cities, towns, or other regions). With NC-CA, operators can utilize all available frequency bands across their network, regardless of the location, to provide higher data speeds, better coverage, and improved network performance to their customers. NC-CA also enables operators to deploy new services and applications more quickly and efficiently, without the need to invest in additional physical infrastructure. Intraband (IB) NC-CA is when the carriers to be aggregated are associated to different frequencies, but within the same frequency band. In IB NC-CA, carriers may be contiguous or non-contiguous, however, it may be advantageous to use a common LNA and AGC to reuse hardware and reduce chipset costs. Thus, a UE may combine different carriers within the same frequency band received from different base stations (e.g., gNBs) using aspects described in the present disclosure, to increase communication speeds.

FIG. 7 shows a table of UE characteristics, according to some aspects. Aspects of the present disclosure include network management processes and coordination between the different network elements, such as base stations and core network nodes, to promote seamless operation and optimal performance with NC-CA. For example, in an Intra-band Non-collocated CA scenario, two issues are observed. From the perspective of a UE, a larger power imbalance may be present between component carriers (CCs), which can be as large as 25 dB. Further, larger time arrival difference may be present between CCs observed by the UE. For example, a round-trip delay (RTD) may be observed of greater than 3 us or the cyclic prefix associated to the subcarrier spacing of the signal.

A new PHY channel configuration and PDSCH scheduling may be supported to maximize aggregate throughput for a UE, such as with UE Type 3a/3b, which is described in the UE Type Table 702, or other UE types. In particular, the table shows for type 3a/3b that the power imbalance may be between 6 and 25 dB partial range, however, aspects described may also benefit other UE types. As mentioned, LNA Analog Gain change can distort some symbols in some situations. For example, symbol 0 or symbol 13 may be distorted when RTD>Cyclic Prefix (CP) length for the victim carrier. To avoid severe throughput loss, if RTD>CP length, the network can restrict to limited PDSCH grants depending on whether symbol 0 or symbol 13 are corrupt. Without any coordination between the network and the UE, the network may need to schedule a reduced (e.g., restricted) PDSCH in every slot. Throughput can be increased further, based on the described coordination processes related to automatic gain control.

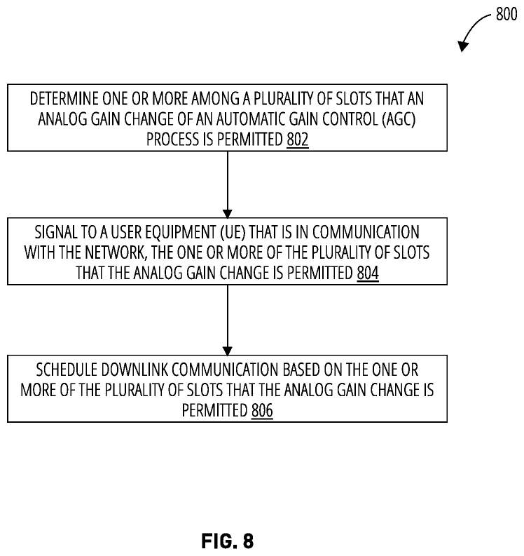

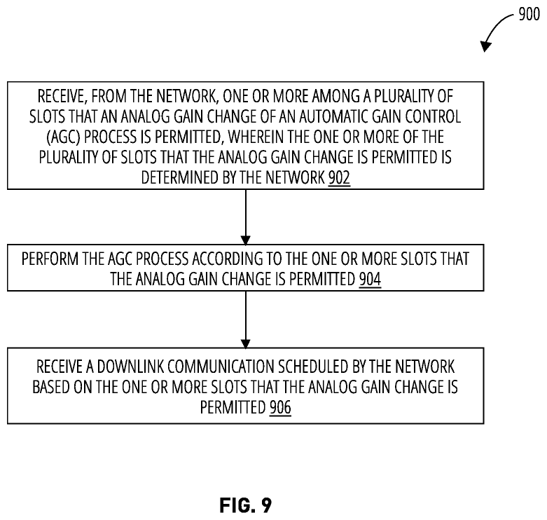

FIG. 8 shows a method 800 for coordination of AGC from a network perspective, in accordance with some examples. The method 800 may be performed by processing logic of a base station, which may include a processor coupled to a transceiver where the processor may execute instructions stored on computer-readable memory to perform the method described.

At block 802, processing logic determines one or more among a plurality of slots that an analog gain change of an automatic gain control (AGC) process is permitted. In an example, determining the one or more of the plurality of slots that the analog gain change is permitted includes receiving one or more network measurements from the UE, determining a cadence of the analog gain change according to the one or more network measurements from the UE, and determining the one or more slots based on the determined cadence of the analog gain change. For example, the one or more network measurements may include a channel status information reference signal (CSI-RS) measurement of the network taken by the UE and provided to the network. Additionally, or alternatively, the cadence and the one or more slots may be determined by the network based on the network measuring UE speed (e.g., Doppler spread).

At block 804, processing logic signals to a user equipment (UE) that is in communication with the network, the one or more of the plurality of slots that the analog gain change is permitted. This may be performed through any downlink signaling from the network to the UE, or through radio resource control (RRC) signaling from the network to the UE. The signaling from the network to the UE may include a cadence (e.g., every X number of slots), or a callout to each specific slot number by a signaled bitmap or other appropriate mechanism.

In an example, signaling to the UE the one or more slots that the analog gain change is permitted includes signaling an integer to the UE. For example, the network may signal an integer ‘x’ to indicate that an analog gain change is permitted every ‘x’ slots. For example, if the network determines that an analog gain change is permitted every four slots, the network may signal the integer ‘4’. In another example of how network may signal which slots an analog gain change is permitted, analog gain change may be associated to specific time domain division (TDD) configuration patterns. For example, the UE may be permitted to only update analog gain in “special slots” that are defined in a given TDD pattern. The cadence of the analog gain change may be determined based on either measurements and/or signaling from the UE which may perform its own measurements and not necessarily report them to the network, but report a “processed version/decision” to the network.

In an example, the UE may apply the integer as a modulo parameter to each of the plurality of slots to obtain the one or more of the plurality of slots that the analog gain change is permitted. If the result is zero, the UE may perform an analog gain change, otherwise it will not. For example, at slot number is 8, assuming the received integer is 4, 8 mod 4=0, so the UE may perform the analog gain change. At slot number 9, 9 mod 4=1, so the UE will not perform an analog gain change, but may still perform a digital gain change.

In some examples, signaling which slots the analog gain change is permitted may include signaling which slots the analog gain change is not permitted, and the UE and network may operate under the assumption that analog gain change is permitted in those slots not included. The exact format of how the slots where analog gain change is permitted are indicated from the network to the UE may vary.

In an example, in response to receiving the signaling from the UE that includes the one or more of the plurality of slots that the analog gain change is permitted, the UE performs an AGC process according to those one or more slots that the analog gain change is permitted (and those that where they are not). The AGC process may include performing an analog gain change during the one or more of the plurality of slots that the analog gain change is permitted and not performing the analog gain change during remaining slots of the plurality of slots. The UE may perform a digital gain change during any of the slots, including in the remaining slots of the plurality of slots where the analog gain change is not performed.

At block 806, processing logic schedules downlink based on the one or more of the plurality of slots that the analog gain change is permitted. In one example, scheduling downlink may include scheduling a restricted physical data shared channel (PDSCH) for each of the one or more of the plurality of slots that the analog gain change is permitted. For each remaining slots of the plurality of slots, processing logic may schedule a PDSCH with a full range of orthogonal frequency division multiplexing (OFDM) symbols. It should be understood that aspects described related to PDSCH may also apply to other PHY channels.

In an example, the restricted PDSCH may comprise a full range of OFDM symbols except for a first symbol. This restricted PDSCH (at the restricted slot) may still have use symbol 1 through symbol 13 for data transport, but not symbol 0.

In another example, the restricted PDSCH comprises a full range of OFDM symbols except for a last symbol. This restricted PDSCH (at the restricted slot) may still have use symbol 0 through symbol 12 for data transport, but not symbol 13.

The network schedules the restricted PDSCH slots in coordination with the UE performing AGC, so that the restricted PDSCH slots coincide with UE's performance of analog gain control during those same slots. Analog gain change cadence is determined based on network measurement, and restricted slots are coordinated between the UE and the network so that each analog gain change may occur according to the scheduling and slots where the analog gain changes are not permitted are scheduled as unrestricted.

FIG. 9 shows a method 900 for coordination of AGC from a UE perspective, in accordance with some examples. The method 900 may be performed by processing logic of a UE, which may include a baseband processor, where the processor may execute instructions stored on computer-readable memory to perform the method described.

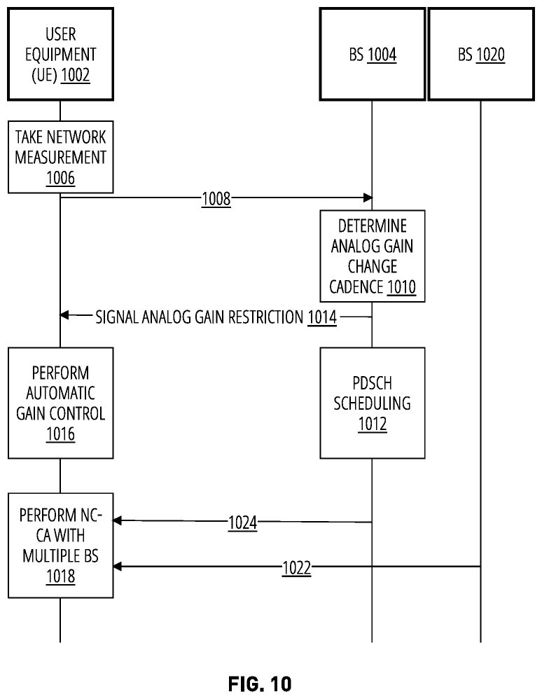

At block 902, processing logic receives, from the network, one or more among a plurality of slots that an analog gain change of an automatic gain control (AGC) process is permitted, wherein the one or more of the plurality of slots that the analog gain change is permitted is determined by the network. For example, those slots where the analog gain change is permitted may be determined by the network based on the descriptions provided in relation to FIG. 8 or FIG. 10, or in other sections of the present disclosure.

At block 904, processing logic performs the AGC process according to the one or more slots that the analog gain change is permitted. For example, processing logic may adjust one or more parameters that adjusts behavior of a low noise amplifier 612 or analog digital converters 614, or any components in between, to change an analog gain 606 in the input signal 602 in slots that the analog gain change is permitted, and not in the slots where it is not permitted. Digital gain change may be performed in any of the slots. In an example, the UE may receive an integer value indicating a cadence. The UE may apply this integer as a modulo parameter to each of the slot numbers, and based on the result, apply analog gain change or not. For example, if the result of the modulo operation is zero, the UE may determine that analog gain change is permitted in this slot. Simultaneously, the network may schedule a restricted PDSCH in those slots.

At block 906, processing logic may receive a downlink scheduled by the network based on the one or more slots that the analog gain change is permitted. For example, the UE may receive PDSCH signaling from the network. The UE may perform AGC when receiving the PDSCH signaling, in accordance with the permitted slots described at block 904. Thus, the UE is configured to perform analog gain control only with slots that coincide with the network's scheduling of restricted PDSCH slots.

FIG. 10 shows a diagram illustrating example operations for coordinating automatic gain change (AGC) between user equipment and a network, in accordance with some aspects. User equipment 1002 may be in communication with a network which may comprise one or more base stations such as base station 1004 and base station 1020. Base station 1004 may be referred to as a serving cell and base station 1020 may be referred to as a neighbor cell. Coverage from base stations 1004 and 1020 with respect to UE 1002 may overlap.

User equipment 1002 may perform operations described such as, for example, with respect to method 900. Similarly, base station 1004 may perform operations described such as, for example, with respect to method 800.

As described, an analog gain change of the UE's RX chain may introduce phase jumps for PDSCH and severely degrade decoding performance. Therefore, it is beneficial to keep physical (PHY) channels PDSCH and/or PDCCH away from impacted OFDM symbols (e.g., symbol 0, symbol 13, or both), in addition to any reference signal such as, for example, CSI-RS or another reference signal.

In one aspect, UE 1002 and the network (e.g., Bs 1004 and 1020) may coordinate with each other to indicate and agree on when phase jumps may occur.

At block 1006, UE may take a network measurement. For example, UE may measure a reference signal (e.g., CSI-RS) that is emitted from the network (e.g., BS 1004). At block 1008 UE may provide this measurement to the UE. The measurement may include a signal strength, an index of the reference signal, and/or other value. In some examples, the measurement may include a CSI reference signal received power (CSI-RSRP) which may be defined as the linear average over the power contributions of the resource elements of the antenna ports, which carry CSI-RS configured for RSRP measurements, a CSI received signal strength indicator (CSI-RSSI) which may be defined as the linear average of the total received power observed only in the OFDM symbols, in which CSI-RS is present; and/or CSI reference signal received quality (CSI-RSRQ) which may be defined as a ratio of CSI-RSRP to CSI-RSSI. Network measurements may be provided to the network in a network measurement report.

At operation 1010, the network determines an analog gain change cadence 1010 in which the UE may perform an analog gain change to its receiver chain. Based on the measured quality received from UE 1002, the BS 1004 may calculate an optimal analog gain change cadence. For example, if the quality is above a threshold, the network may schedule analog gain change at a first cadence, and if the quality does not satisfy the threshold, the network may schedule the analog gain change at a second cadence that is lower than the first cadence. In some examples, as the quality increases, the permitted cadence may also be increased and as measured quality decreases, the permitted cadence is decreased.

The determined cadence may comprise how often the UE may perform the analog gain change, or in which specific slots the gain change may occur, or both. For example, at operation 1010, BS 1004 may determine that the analog gain change is permitted every two slots, or every three slots, or on slot numbers X, Y, and Z. The UE and network may operate under the assumption that an analog gain change is not permitted in the remaining unmentioned slots. As discussed, when an analog gain change occurs, a phase jump is expected. If the network precludes analog gain in one or more slots, the UE will only update the digital gain (and not the analog gain) in those slots, thereby precluding phase jumps in those slots.

At operation 1014, BS 1004 may signal the UE with the slots in which analog gain change is restricted to. In an example, this signal may include an integer which the UE may use to perform a modulo operation on each slot, as described. In other examples, the cadence or restricted slots may be indicated through a different mechanism, such as by providing the exact slot number that the analog gain change may occur.

At block 1016, the UE may perform automatic gain control based on the slot information provided by BS 1004. The UE may restrict analog gain changes during those specified slots where the network indicated the restriction.

Simultaneously, BS 1004 may perform PDSCH scheduling 1012 also in accordance with the analog gain change cadence determined at block 1010. Those slots where the analog gain change is not permitted may utilize the complete range of OFDM symbols for data transport. Similarly, BS 1004 may schedule those slots where the analog gain change is permitted as restricted slots where one or more symbols (e.g., the first symbol or the last symbol) are not utilized for data transport. Thus, the UE 1002 and network (e.g., BS 1004) may coordinate the PDSCH scheduling with the performance of analog gain changes so that slots where UE may perform an analog gain change coincide with restricted slots, and slots that the UE may not perform an analog gain change coincide with unrestricted slots (utilizing the full range of OFDM symbols).

At block 1018, the UE 1002 may perform one or more Intra-band Non-collocated (NC) carrier aggregation (CA) operations based on the analog gain change permissions and PDSCH scheduling as agreed upon between the UE 1002 and BS 1004. For example, the UE may receive downlink communications 1024 and 1022 from BS 1004 and BS 1020 which may be non-collocated (e.g., at different sites) and in the same frequency band (e.g., intra-band). The UE 1002 may perform analog gain control during only the permitted slots. BS 1004 and BS 1020 may send downlink (1022 and 1024) to the UE with restricted slots at respective carriers that coincide with those permitted slots, and non-restricted slots otherwise. The UE may receive the downlink communications (1022 and 1024) and perform AGC on the received downlink communications according to which slots the analog gain change is permitted, and aggregates the received downlink signals 1024 and 1022 in the process of NC-CA.

Portions of what was described above may be implemented with logic circuitry such as a dedicated logic circuit or with a microcontroller or other form of processing core that executes program code instructions. Thus, processes taught by the discussion above may be performed with program code such as machine-executable instructions that cause a machine that executes these instructions to perform certain functions. In this context, a “machine” may be a machine that converts intermediate form (or “abstract”) instructions into processor specific instructions (e.g., an abstract execution environment such as a “virtual machine” (e.g., a Java Virtual Machine), an interpreter, a Common Language Runtime, a high-level language virtual machine, etc.), and/or, electronic circuitry disposed on a semiconductor chip (e.g., “logic circuitry” implemented with transistors) designed to execute instructions such as a general-purpose processor and/or a special-purpose processor. Processes taught by the discussion above may also be performed by (in the alternative to a machine or in combination with a machine) electronic circuitry designed to perform the processes (or a portion thereof) without the execution of program code.

The present invention also relates to an apparatus for performing the operations described herein. This apparatus may be specially constructed for the required purpose, or it may comprise a general-purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), RAMS, EPROMs, EEPROMs, magnetic or optical cards, or any type of media suitable for storing electronic instructions, and each coupled to a computer system bus.

A machine-readable medium includes any mechanism for storing or transmitting information in a form readable by a machine (e.g., a computer). For example, a machine-readable medium includes read only memory (“ROM”); random access memory (“RAM”); magnetic disk storage media; optical storage media; flash memory devices; etc.

A baseband processor (also known as baseband radio processor, BP, or BBP) is a device (a chip or part of a chip) in a network interface that manages radio functions, such as communicating (e.g., TX and RX) over an antenna.

An article of manufacture may be used to store program code. An article of manufacture that stores program code may be embodied as, but is not limited to, one or more memories (e.g., one or more flash memories, random access memories (static, dynamic, or other)), optical disks, CD-ROMs, DVD ROMs, EPROMs, EEPROMs, magnetic or optical cards or other type of machine-readable media suitable for storing electronic instructions. Program code may also be downloaded from a remote computer (e.g., a server) to a requesting computer (e.g., a client) by way of data signals embodied in a propagation medium (e.g., via a communication link (e.g., a network connection)).

The preceding detailed descriptions are presented in terms of algorithms and symbolic representations of operations on data bits within a computer memory. These algorithmic descriptions and representations are the tools used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be kept in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “transmitting”, “sending”, “selecting,” “determining,” “receiving,” “forming,” “grouping,” “aggregating,” “generating,” “removing,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The processes and displays presented herein are not inherently related to any particular computer or other apparatus. Various general-purpose systems may be used with programs in accordance with the teachings herein, or it may prove convenient to construct a more specialized apparatus to perform the operations described. The required structure for a variety of these systems will be evident from the description below. In addition, the present invention is not described with reference to any particular programming language. It will be appreciated that a variety of programming languages may be used to implement the teachings of the invention as described herein.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing discussion merely describes some exemplary aspects of the present invention. One skilled in the art will readily recognize from such discussion, the accompanying drawings and the claims that various modifications can be made without departing from the spirit and scope of the invention.

1. A method, performed by a network, comprising:
determining one or more among a plurality of slots that an analog gain change of an automatic gain control (AGC) process is permitted; and
signaling to a user equipment (UE) that is in communication with the network, the one or more of the plurality of slots that the analog gain change is permitted; and
scheduling downlink communication based on the one or more of the plurality of slots that the analog gain change is permitted.

2. The method of claim 1, wherein scheduling the downlink comprises: for each of the one or more of the plurality of slots that the analog gain change is permitted, scheduling a restricted physical data shared channel (PDSCH).

3. The method of claim 2, wherein scheduling the downlink comprises: for each of remaining slots of the plurality of slots, scheduling a PDSCH with a full range of orthogonal frequency division multiplexing (OFDM) symbols.

4. The method of claim 2, wherein the restricted PDSCH comprises a full range of OFDM symbols except for a first symbol.

5. The method of claim 2, wherein the restricted PDSCH comprises a full range of OFDM symbols except for a last symbol.

6. The method of claim 1, wherein determining the one or more among the plurality of slots that the analog gain change is permitted includes receiving one or more network measurements from the UE, determining a cadence of the analog gain change according to the one or more network measurements from the UE, and determining the one or more slots based on the determined cadence of the analog gain change.

7. The method of claim 6, wherein the one or more network measurements include a channel status information reference signal (CSI-RS) measurement of the network taken by the UE.

8. The method of claim 1, wherein in response to receiving the one or more of the plurality of slots that the analog gain change is permitted, the UE performs an automatic gain control (AGC) process that includes performing an analog gain change during the one or more of the plurality of slots that the analog gain change is permitted and not performing the analog gain change during remaining slots of the plurality of slots.

9. The method of claim 8, wherein performing the AGC process includes performing a digital gain change during unrestricted slots of the plurality of slots.

10. The method of claim 1, wherein signaling to the UE the one or more slots that the analog gain change is permitted includes signaling an integer to the UE, wherein the UE applies the integer as a modulo parameter to each of the plurality of slots to obtain the one or more of the plurality of slots that the analog gain change is permitted.

11. A method, performed by user equipment (UE) that is in communication with a network, comprising:
receiving, from the network, one or more among a plurality of slots that an analog gain change of an automatic gain control (AGC) process is permitted, wherein the one or more of the plurality of slots that the analog gain change is permitted is determined by the network;
performing the AGC process according to the one or more slots that the analog gain change is permitted; and
receiving a downlink communication scheduled by the network based on the one or more slots that the analog gain change is permitted.

12. The method of claim 11, wherein for each of the one or more of the plurality of slots that the analog gain change is permitted, the network schedules a restricted physical data shared channel (PDSCH).

13. The method of claim 12, wherein for each remaining slot of the plurality of slots, the network schedules the PDSCH with a full range of orthogonal frequency division multiplexing (OFDM) symbols.

14. The method of claim 13, wherein the restricted PDSCH comprises:
the full range of the OFDM symbols except for a first symbol; or
the full range of the OFDM symbols except for a last symbol.

15. (canceled)

16. The method of claim 11, wherein determining, by the network, the one or more of the plurality of slots that the analog gain change is permitted includes receiving one or more network measurements taken by the UE, determining a cadence of the analog gain change according to the one or more network measurements from the UE, and determining the one or more slots based on the analog gain change cadence.

17. The method of claim 11, wherein the one or more network measurements taken by the UE include a channel status information reference signal (CSI-RS) measurement of the network taken by the UE.

18. The method of claim 11, wherein performing the AGC process includes performing an analog gain change during the one or more of the plurality of slots that the analog gain change is permitted and not performing the analog gain change during remaining slots of the plurality of slots.

19. The method of claim 18, wherein performing the AGC process includes performing a digital gain change during the remaining slots of the plurality of slots.

20. The method of claim 11, wherein receiving, from the network, the one or more among a plurality of slots that the analog gain change of is permitted includes receiving an integer, and performing the AGC process includes applying the integer as a modulo parameter to each of the plurality of slots to obtain the one or more of the plurality of slots that the analog gain change is permitted.

21. A user equipment (UE), comprising:
a memory configured to store one or more instructions; and
one or more processors configured to, when executing the one or more instructions, cause the UE to:
receive, from a network, one or more among a plurality of slots that an analog gain change of an automatic gain control (AGC) process is permitted, wherein the one or more of the plurality of slots that the analog gain change is permitted is determined by the network;
perform the AGC process according to the one or more slots that the analog gain change is permitted; and
receive a downlink communication scheduled by the network based on the one or more slots that the analog gain change is permitted.
